(19) United States
(12) Patent Application Publication
(10) Pub. No.: US 2010/0294336 A1
(43) Pub. Date: Nov. 25, 2010

(54) CENTER TAPPED RECEIVER

(75) Inventors: Eric C. Johnson, Mountain View, CA (US); Alexander D. Zbrozek, Stanford, CA (US)

Correspondence Address: Beyer Law Group LLP, P.O. BOX 1687, Cupertino, CA, 95015-1687, US

(73) Assignee: SKYLINE SOLAR, INC., Mountain View, CA (US)

(21) Appl. No.: 12/784,360

(22) Filed: May 20, 2010

Related U.S. Application Data
(60) Provisional application No. 61/180,694, filed on May 22, 2009.

(51) Int. Cl. H01L 31/042; H01L 31/00; H01L 31/18

(52) U.S. Cl. 136/244; 136/256; 438/65; 257/E31.127; 257/E31.117

(57) ABSTRACT

A variety of arrangements and methods relating to solar energy collectors and/or solar receivers are described. In one aspect of the invention, a solar receiver includes a photovoltaic cell and a conductive bar that is mounted on the photovoltaic cell. One or more protective covers are positioned over the conductive bar and the cell. Each of the protective covers includes a top and an opposing bottom surface and a side beveled surface. The top and bottom surfaces of the protective covers are substantially parallel to the face of the photovoltaic cell. The side beveled surface is positioned over the conductive bar and is arranged to reflect incoming sunlight towards a portion of the cell that is not covered by the conductive bar.

### CROSS-REFERENCE TO RELATED APPLICATIONS

This application claims priority benefit of U.S. Provisional Patent Application No. 61/180,694, filed May 22, 2009, which is incorporated herein by reference in its entirety for all purposes.

### FIELD OF THE INVENTION

The present invention generally relates to solar energy collection. More specifically, the present invention pertains to solar energy collector and solar energy receiver designs arranged to help improve the efficiency of a photovoltaic module

### BACKGROUND OF THE INVENTION

A basic building block of a photovoltaic power system is the photovoltaic cell. Generally, a photovoltaic cell is made from a semiconductor material with electrically conductive elements situated on the cell surface. When sunlight falls on the cell, energy from the sunlight releases electrons in the semiconductor material, which migrate to the electrically conductive elements. Electrical current is generated as the electrons flow through an external load connected with the cell.

There are a wide variety of ways to arrange photovoltaic cells. FIG. 1 illustrates one example of a conventional photovoltaic cell 100, which includes a semiconductor material 102 that is overlaid with multiple fingers or conductive traces 104. The conductive traces 104 are physically and electrically connected to the bus bars 106. The photovoltaic cell 100 is part of a non-concentrating photovoltaic power system. Accordingly, sunlight is ideally received over the entire face of the photovoltaic cell 100.

In the illustrated embodiment, the conductive traces 104 are distributed across the cell 100. To limit the blockage of sunlight, each conductive trace 104 is made much thinner than the bus bar 106. The bus bars 106 are coupled to an external device (not shown) and are part of the conductive path that carries photo generated current from the photovoltaic cell 100 to the external device.

While existing arrangements and methods for solar receivers and photovoltaic cells work well, there are continuing efforts to improve their efficiency in a cost-effective manner, particularly for receivers optimized for use in a concentrated PV system.

### SUMMARY OF THE INVENTION

The present invention relates to a variety of methods and arrangements for improving the efficiency of a solar receiver. In one aspect of the invention, a solar receiver includes a photovoltaic cell having a conductive bar situated on the front surface of the photovoltaic cell. One or more protective covers are positioned over the cell. Each of the protective covers includes a top and an opposing bottom surface and a side beveled surface. The top and bottom surfaces of the protective covers are substantially parallel to the face of the photovoltaic cell. The side beveled surface is positioned over the conductive bar and is arranged to reflect incoming sunlight towards a portion of the cell that is not covered by the conductive bar. As a result, sunlight that might otherwise fall on the conductive bar is not wasted and is instead directed towards the cell so that it can contribute to the generation of electricity. Additional embodiments relate to methods for forming the above solar receiver.

In another aspect of the invention, a solar energy collector for use in a solar energy collection system will be described. The solar energy collector includes a photovoltaic cell having a bus bar that is situated on the cell surface. The solar energy collector also includes a reflective surface that is coupled with the solar receiver. The reflective surface is arranged to concentrate incident sunlight to form a flux line on the photovoltaic cell such that the flux line covers the bus bar without entirely covering the face of the photovoltaic cell. Because the flux line is formed in the vicinity of the bus bar, the photo generated electrons do not have to travel far to reach the bus bar. This helps reduce the series resistance of the solar receiver.

### BRIEF DESCRIPTION OF THE DRAWINGS

The invention and the advantages thereof, may best be understood by reference to the following description taken in conjunction with the accompanying drawings in which:

FIG. 1 is a diagrammatic top view of an exemplary prior art photovoltaic cell.

FIG. 2 is a diagrammatic perspective view of a solar energy collector according to a particular embodiment of the present invention.

FIG. 3 is a diagrammatic top view of a photovoltaic cell with a central bus bar according to a particular embodiment of the present invention.

FIGS. 4A-4C are diagrammatic top views of photovoltaic cells with different bus bar arrangements according to various embodiments of the present invention.

FIGS. 5-6 are diagrammatic side views of solar receivers that each include an encapsulated bus bar and one or more protective covers according to various embodiments of the present invention.

FIG. 7 is a diagrammatic side view of a solar receiver with a top protective layer according to a particular embodiment of the present invention.

FIG. 8 is a diagrammatic side view of a solar receiver that includes at least two adjacent photovoltaic cells according to a particular embodiment of the present invention.

FIG. 9-11 are diagrammatic side views of solar receivers that include protective covers with substantially parallel, beveled surfaces according to various embodiments of the present invention.

FIG. 12 is a graph of the angle of incidence of light on a photovoltaic cell as a function of the angle of incidence of light on a protective cover according to a particular embodiment of the present invention.

FIG. 13 is a flow chart illustrating a method for forming a solar receiver according to a particular embodiment of the present invention.

In the drawings, like reference numerals are sometimes used to designate like structural elements. It should also be appreciated that the depictions in the figures are diagrammatic and not to scale.

### DETAILED DESCRIPTION OF THE PREFERRED EMBODIMENTS

The present invention relates generally to arrangements and methods for collecting solar energy. Some aspects of the invention relate to various types of solar receiver and collector designs that help maximize the amount of energy that is collected from incoming sunlight.

When solar radiation strikes a photovoltaic cell, it releases free electrons in the semiconductor material of the cell that can be used to generate electricity. It is desirable to form a path for the electrons to follow that has minimal electrical resistance. The semiconductor material itself is a relatively poor electrical conductor. The standard approach is to position electrically conductive elements or circuitry (e.g., electrically conductive traces or bus bars) on the cell in the vicinity of the electrons, so that the electrons can be channeled through the circuitry to generate an electrical current.

While effective, this approach involves tradeoffs. Typically, non-concentrating photovoltaic power systems position a photovoltaic cell so that it receives a relatively uniform amount of sunlight across almost the entire face of the cell. Thus, free electrons may be generated at almost any location on the cell. Circuitry, such as bus bars or conductive traces, may be densely arranged across the face of the cell to capture the electrons. However, the more densely such circuitry is laid over the face of the cell, the more sunlight is blocked by the circuitry itself and the lower the overall light to electric conversion efficiency of the device.

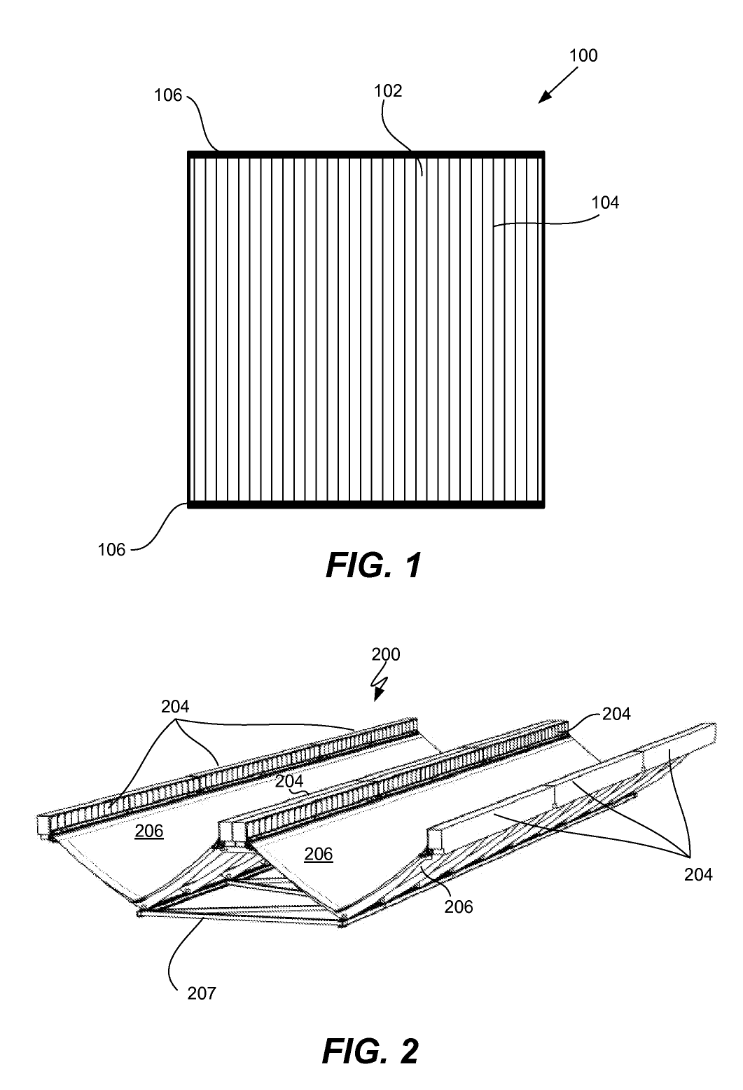

Efforts to minimize such blockage may incur additional tradeoffs. As seen in FIG. 1, some of the circuitry, such as the conductive traces 104, can be made very thin. Each conductive trace 104 covers less of the cell 100 than the wider bus bar 106 and thus blocks less of the sunlight. However, the narrower the conductive trace, the higher its electrical resistance. A disadvantage of the arrangement illustrated in FIG. 1 is that the electrons may have to traverse a long path through the conductive traces 104 to reach the bus bars 106 at the edges of the cell 100.

The present invention involves solar receiver and collector designs arranged to address one or more of the above concerns. Various implementations involve a solar collector that concentrates incident sunlight to form a flux line on a solar receiver. The flux line does not cover the entire face of a photovoltaic cell on the receiver, but is generally limited to a particular region of the cell. Preferably, the solar receiver is arranged so that one or more bus bars on the cell are positioned underneath the flux line. This approach limits the distance that the photo generated current must travel to reach the bus bar. It also may reduce the need to position circuitry across the entire face of the cell, which helps conserve material and reduce manufacturing costs.

Some implementations of the present invention relate to solar receiver designs that are arranged to capture sunlight that would otherwise be blocked by a conductive bar (e.g., a bus bar or any other electrically conductive circuitry) on the face of a photovoltaic cell. More specifically, one or more protective covers positioned over the photovoltaic cell each have a side beveled surface that is situated over a conductive bar. The beveled surface reflects light that would otherwise fall on the conductive bar and directs it towards other portions of the cell. As a result, the sunlight is not lost and can be usefully converted into electricity. Although there are existing arrangements for reflecting light away from a bus bar on a solar cell, various approaches described herein do so while helping to minimize the number of additional layers and/or structures in the solar receiver. As a result, the size, weight and the manufacturing costs of the solar receiver may be reduced.

Referring now to FIG. 2, a solar energy collector 200 according to one embodiment of the present invention will be described. The solar energy collector 200, which includes a reflector structure 207, reflector panels 206, and solar receivers 204, is arranged to form a flux line on a photovoltaic cell as described above. That is, the flux line is formed such that it overlaps and/or is in close proximity to one or more bus bars on the cell. The assignee of the present application, Skyline Solar, Inc., has developed various solar energy collectors that may be used with the present invention, including collectors described in patent application Ser. No. 12/100,726, entitled “Dual Trough Concentrating Solar Photovoltaic Module,” filed Apr. 10, 2008, and patent application Ser. No. 12/728,149, entitled “Reflective Surface for Solar Energy Collector,” filed Mar. 19, 2010, which are incorporated by reference in their entirety for all purposes.

The solar energy collector 200 may be arranged in a wide variety of ways, depending on the needs of a particular application. In the illustrated embodiment, for example, the reflector structure 207 supports multiple reflector panels 206 and solar receivers 204. Each solar receiver 204 may include one or more heat sinks and multiple photovoltaic cells that are connected in a cell string. Each reflector panel 206 is arranged to reflect incident sunlight towards a solar receiver 204 such that a flux line is formed on a photovoltaic cell on the receiver. In a preferred embodiment, the flux line covers a central region of the cell where one or more bus bars are situated. The solar energy collector 200 may be arranged to track movements of the sun so that the flux line is generally incident on the faces of the cells.

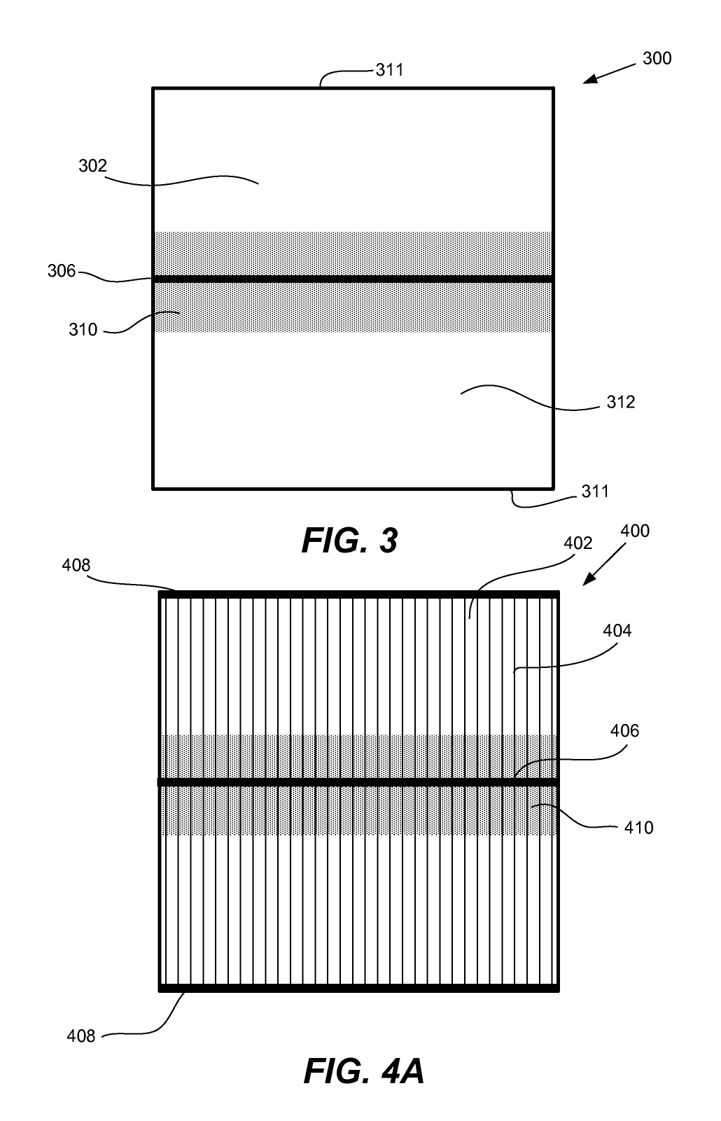

Referring now to FIG. 3, a photovoltaic cell 300 and its corresponding flux line 310 according to a particular embodiment of the present invention will be described. The photovoltaic cell 300 includes a semiconductor material 302 that underlies a bus bar 306. The bus bar 306 is electrically and physically coupled with an external device that receives electrical current generated by the photovoltaic cell 300. A flux line 310 is formed on the face of the solar receiver 204 by the reflector panel 206 of FIG. 2. The solar receiver 204 has a plurality of photovoltaic cells 300 arranged in a generally linear fashion such that the flux line 310 overlaps the cells.

The reflector panel 206 is arranged to direct and concentrate light onto the cell 300 so that the flux line 310 covers a central region of the cell 300 and overlaps the bus bar 306. As a result, electrical current generated by the flux line 310 needs to travel only a short distance to reach the bus bar 306. This helps improve the efficiency of the photovoltaic cell 300. The close proximity of the bus bar 306 to the flux line 310 is particularly helpful in improving the efficiency of solar concentrating systems, such as the collector illustrated in FIG. 2, where current densities and resistive losses can be higher than in non-concentrating systems.

The bus bar 306 is an electrically conductive structure that is arranged to facilitate the flow of photo generated current across the face of the cell 300. In the illustrated embodiment, the bus bar is a straight bar of electrically conductive material that is formed on the face of the cell 300 and directly connects two opposing sides of the cell 300, although other arrangements are also possible. In some embodiments, the bus bar 306 is physically and electrically connected to associated fingers or conductive traces that fan out from the bus bar 306. Generally, in these implementations the bus bar 306 is substantially wider than any single associated finger. By way of example, a bus bar can have a width of approximately 1 mm or more, while each associated finger can have a width of approximately 200 microns or less. It should be noted that this application also sometimes refers to a conductive bar, which should be understood as any electrically conductive structure on the cell 300 (e.g., a finger or conducive trace, a bus bar, other suitable circuitry, etc.) that is arranged to help carry electrical current.

The flux line 310 can be formed in various ways. In the illustrated embodiment, for example, the flux line 310 forms a continuous, strip-like region of concentrated sunlight on the face of the cell 300. In still other embodiments, the flux line 310 may have a different location or shape e.g., it may cover edge portions of two adjacent cells, it may have a dip at its center, etc. Preferably, the flux line does not extend to the top and bottom edges 311 of the photovoltaic cell 300 and does not cover the entire face of the cell 300. Accordingly, there are substantial buffer regions 312 that separate the flux line 310 from the edges 311 of the cell 300. One advantage of such a design is that any misalignment of the reflective surface 206 of FIG. 2 that helps form the flux line 310 is less likely to cause reflected light to entirely miss the photovoltaic cell 300.

Because the flux line 310 is formed at a generally known, predetermined location on the face of the cell 300, one or more bus bars can be selectively positioned on the cell 300 to help shorten the path that the photo generated electrons must travel to reach the bus bars. In the illustrated embodiment, for example, the bus bar 306 extends approximately along a central, bisecting axis of the flux line 310, although this is not a requirement. Various approaches involve positioning one or more bus bars 306 in almost any location within the flux line 310. It should be noted that the present invention contemplates a wide variety of arrangements of the flux line 310, the photovoltaic cell 300 and bus bar(s) 306.

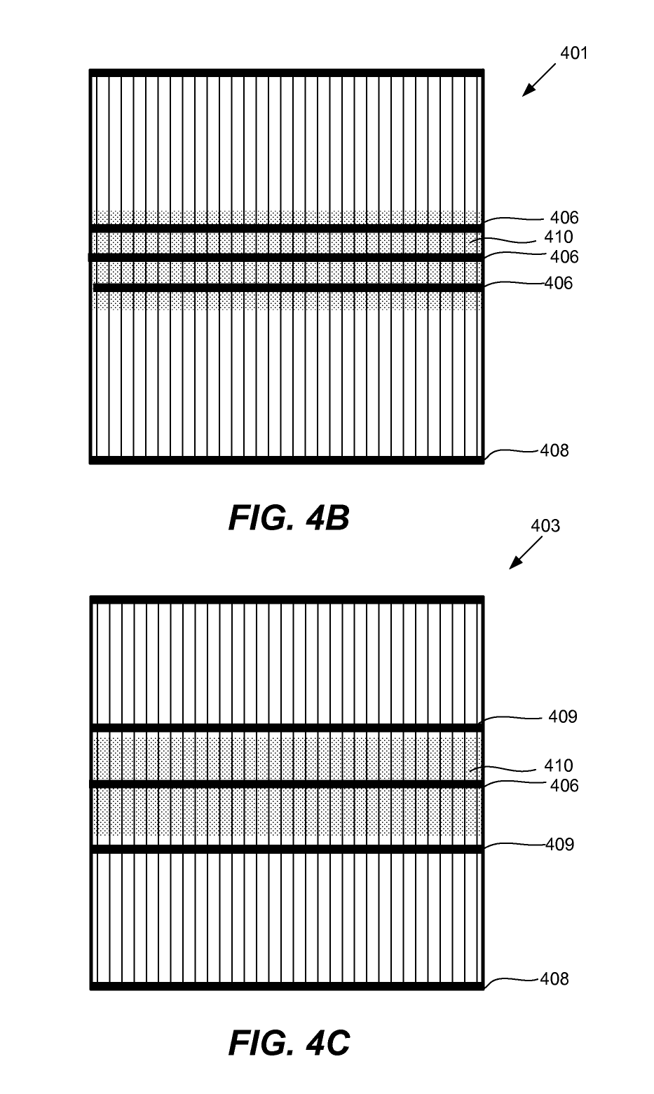

FIGS. 4A-4C illustrate some of these arrangements. FIG. 4A illustrates a photovoltaic cell 400 that includes semiconductor material 402, a central bus bar 406 and edge bus bars 408. The flux line 410 overlaps the central bus bar 406 but not the edge bus bars 408. Additionally, a plurality of fingers or conductive traces 404 physically and electrically connect the central bus bar 406 with the edge bus bars 408. Each bus bar 406 and 408 is generally much wider than any individual conductive trace 404. In the illustrated embodiment, multiple conductive traces 404 fan out from and are each arranged substantially perpendicular to the central bus bar 406, although other arrangements are also possible.

The solar receiver 401 of FIG. 4B is similar to that of FIG. 4A, except that there are multiple central bus bars 406 that are overlapped by the flux line 410. FIG. 4C illustrates another solar receiver 403, where some of the bus bars 409, unlike the central bus bar 406, are situated in close proximity to but are not directly overlapped by the flux line 410. That is, the bus bars 409 are adjacent to and just outside the periphery of the flux line 410. Many other arrangements of a flux line, bus bars, conductive bars and/or conductive traces are also possible. For example, the edge bus bars and/or conductive traces of FIGS. 4A-4C are optional and do not exist in some embodiments.

It should be appreciated that the idea of concentrating light in the form of a flux line directly over a bus bar is quite counterintuitive. As discussed earlier in connection with FIG. 1, a common practice is to take the opposite approach i.e., to push the bus bars to a location, such as the very edge of a cell, where they will minimally interfere with the incoming sunlight. To help reduce losses of solar energy related to the bus bars, various implementations of the present invention involve a solar receiver with a protective cover that reflects light away from a bus bar and towards a suitable portion of a photovoltaic cell. Thus, the light can be converted into electricity rather than wasted. Some of these implementations will be described below.

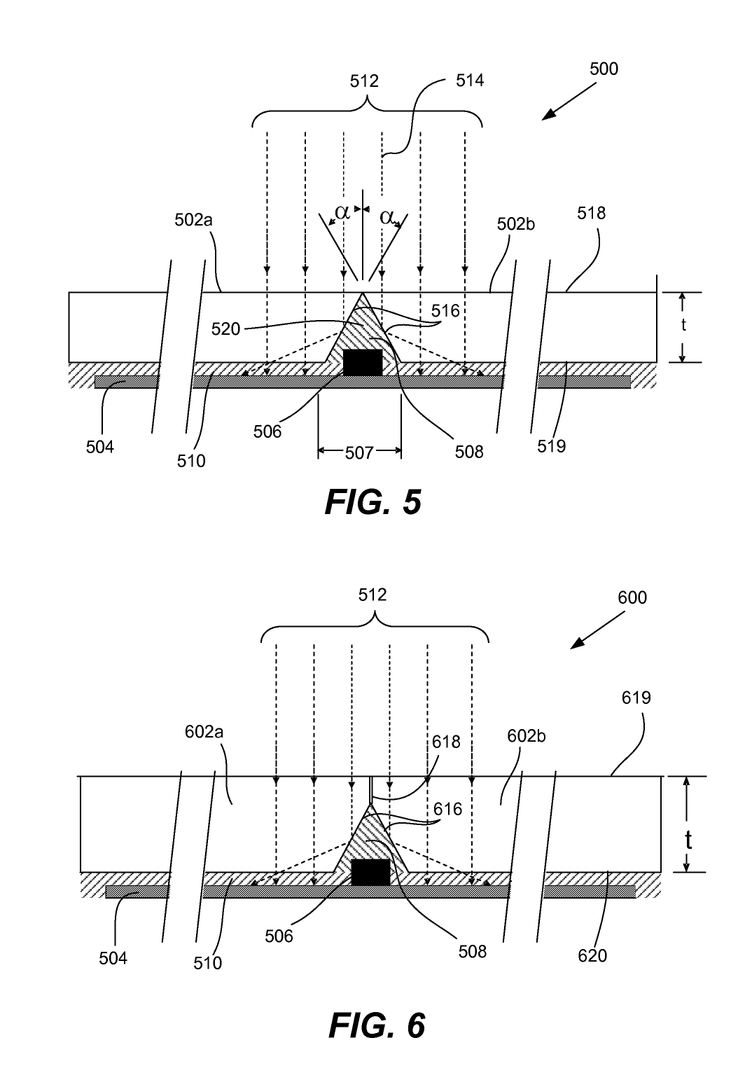

Referring now to FIG. 5, a cross-sectional view of a solar receiver 500 according to one embodiment of the present invention will be described. Solar receiver 500 includes a photovoltaic cell 504, bus bar 506, first and second encapsulants 508 and 510, and first and second protective covers 502a and 502b. A flux line 512 illuminates a central region of the photovoltaic cell 504 and overlaps the bus bar 506. The first encapsulant 508 surrounds the bus bar 506 and is positioned between each protective cover, 502a and 502b, and the bus bar 506.

The first and second protective covers 502a and 502b each include a side beveled surface 516. The beveled surfaces 516 of the protective covers are positioned adjacent to one another and angled over the encapsulated bus bar 506 so that they reflect sunlight that would otherwise fall on the encapsulated bus bar 506. Accordingly, the beveled surfaces 516 form a shadowed region 507 over the encapsulated bus bar 506. As indicated by incoming sunlight 514, the reflected sunlight is redirected to a portion of the cell 504 that is not covered by the encapsulated bus bar 506. Thus, the sunlight is converted into electricity rather than being absorbed by the encapsulated bus bar 506 and lost. It should be appreciated that although FIG. 5 depicts the incoming sunlight 514 as being normally incident to the face of the photovoltaic cell 504, this is not a requirement. That is, light coming from other angles towards the encapsulated bus bar 506 may also be redirected to other portions of the cell 504 and converted into electricity. The angle α, which is the angle between a beveled surface 516 and a reference line that runs perpendicular to the face of the cell 504, may be between 20 and 40 degrees, although smaller and larger angles are also possible. In some embodiments, the angle α is substantially the same for the beveled surfaces 516 of the protective covers 502a and 502b, although this is not a requirement.

To facilitate the redirection of light, beveled surfaces 516 may be coated with silver or any other suitable material with highly reflective properties. Some implementations do not involve such reflective coatings and/or reflect light at least in part through total internal reflection. In some embodiments, the beveled surfaces 516 are polished to specularly reflect at least a majority of the received sunlight.

The aforementioned features of the protective covers 502a and 502b offer several advantages over the prior art. As is known by persons of ordinary skill in the art, placing glass protective covers over a photovoltaic cell to protect them from environmental damage is a common practice. However, to the best knowledge of the inventors, it is novel to use a beveled surface of the protective cover to also reflect sunlight away from a bus bar. Accordingly, there is no need to add a separate reflector structure over the bus bar to accomplish the same objective. In some embodiments, there is no structure in the solar receiver between the protective covers 502a and 502b and the bus bar 506, which, during the normal operation of the receiver, is arranged to reflect light away from the encapsulated first bus bar 506 and towards a portion of the cell that is not covered by the encapsulated first bus bar 506. Such approaches can help contribute to a lighter, thinner receiver and lower production costs.

The thinness of the solar receiver 500 is also promoted by the way in which the protective covers 502a and 502b are shaped and arranged over the encapsulated bus bar 506. In the illustrated embodiment, for example, the beveled surfaces 516 of the protective covers 502a and 502b cooperate to form a v-shaped groove 520 directly over the encapsulated bus bar 506. The bus bar 506 protrudes at least partially into this groove, which allows the overall solar receiver 500 to be thinner than would be the case if each protective cover was a simple, flat, rectangular sheet. Since less space is required between the bottom surface 519 of the protective covers and the cell 504 to make room for the bus bar 506, less of the second encapsulant 510 needs to be used to fill that space. The groove 520 can also provide room for a thicker bus bar, which generally conducts electricity with less resistive loss than a thinner bus bar.

The first encapsulant 508, which is positioned between each protective cover 502a and 502b and the bus bar 506, helps prevent contaminants from reaching the bus bar 506. Conveniently, the first encapsulant 508 is also well positioned to protect any reflective coating on the beveled surfaces 516, as such coatings tend to be easily corroded or oxidized by exposure to moisture. In the illustrated embodiment, the first encapsulant 508 surrounds and seals over the bus bar 506 and is in direct contact with and at least partially fills a groove 520 formed by the (coated) beveled surfaces 516. Butyl rubber works well as a material for the first encapsulant 508, although other suitable materials may also be used. Since light is being deflected away from the bus bar 506, the overlying first encapsulant 508 need not be optically transparent. In fact, in some applications the ability to use an optically non-transparent encapsulant 508 may be advantageous, since non-transparent materials sometimes make for better sealants than transparent ones. Placing a non-transparent encapsulant between the photovoltaic cells and protective cover is counterintuitive, since generally high optical transmission is required in this region. The present invention relaxes this requirement by reflecting sunlight away from the non-transparent encapsulant to a region of the photovoltaic cell where it may be absorbed and produce useful energy.

The face of the photovoltaic cell 504 may also be covered by an optional second encapsulant 510. The second encapsulant 510 helps protect the underlying photovoltaic cell 504. In various embodiments, the second encapsulant 510 is made of ethyl-vinyl acetate (EVA) or silicone, although other optically transparent materials may also be used. Given that the first encapsulant 508 may be made of an optically non-transparent substance, the composition of the first and second encapsulants 508 and 510 may differ. Preferably, the second encapsulant 510 is compliant and arranged to compensate for differential thermal expansion. In some embodiments, the refractive index of the second encapsulant 510 is substantially similar to or approximately the same as the refractive index of the overlying protective covers 502a and 502b, which can help reduce reflection at the interface between the layers.

Generally, the protective covers 502a and 502b are sheet-like structures that are laid over the photovoltaic cell 504. They may be formed of glass or any other suitable, optically transparent material. In the illustrated embodiment, each protective cover 502a and 502b includes a top surface 518 and an opposing bottom surface 519 that are connected together with the side beveled surface 516. The top and bottom surfaces 518 and 519 of the protective covers 502a and 502b are substantially parallel with the face of the photovoltaic cell 504. The separate protective covers 502a and 502b are arranged end to end so that their top surfaces 518 are substantially coplanar. The dimensions of the protective covers may vary for different applications. For example, a thickness t for the protective cover of between approximately 3 and 10 mm works well. Note that in FIG. 5 and subsequent figures various features that may be part of a solar receiver, such as a heat sink or mounting surface for the photovoltaic cells have been omitted for clarity.

Referring now to FIG. 6, a solar receiver 600 according to another embodiment of the present invention will be described. The solar receiver 600 has various components that are generally similar to the ones shown in FIG. 5, including a photovoltaic cell 504, a bus bar 506, a first encapsulant 508, an optional second encapsulant 510 and a flux line 512 that overlaps the bus bar 506. The sides of the protective covers 602a and 602a, however, are structured differently in that they lack uniform slopes. In the illustrated embodiment, for example, the side of each protective cover 602a and 602b includes a beveled surface 616 that forms a corner with an additional side surface 618. The adjacent side surfaces 618 are substantially perpendicular to the face of the cell 504 and substantially parallel to one another.

The implementation illustrated in FIG. 6 has several advantages. In the illustrated embodiment, the sides of the protective covers 602a and 602b lack uniform slopes and thus also lack corners with acute angles. Such corners are generally more prone to mechanical damage. Additionally, the side surfaces 618 form an extended region where the protective covers 602a and 602b are adjacent to one another. Preferably, the protective covers 602 and 602b are pressed together along this extended region, which helps promote a tighter seal. In some embodiments, the side surfaces 618 do not exist and the protective covers 602a and 602b form a single, integrally formed structure that is physically connected through the side surfaces 618 illustrated in FIG. 6. In still other embodiments, the adjacent side surfaces 618 may be sealed together using a suitable encapsulant, which may or may not be the same as the first encapsulant 508 or the second encapsulant 510.

The side surfaces 618 may also be involved in the reflection of sunlight. That is, the side surfaces 618 may be arranged to reflect sunlight coming in at an oblique angle of incidence. The reflected light is then directed towards a suitable portion of the underlying cell so that it can be converted into electricity. To enhance its reflectivity, the side surface 618 may be metalized or coated with a highly reflective material (e.g., silver, etc.) In some preferred embodiments, the beveled surfaces 616 and/or the side surfaces 618 of the protective covers 602a and 602b are coated with a reflective material, while the top and bottom surfaces 619 and 620 of the protective covers 602a and 602b are not.

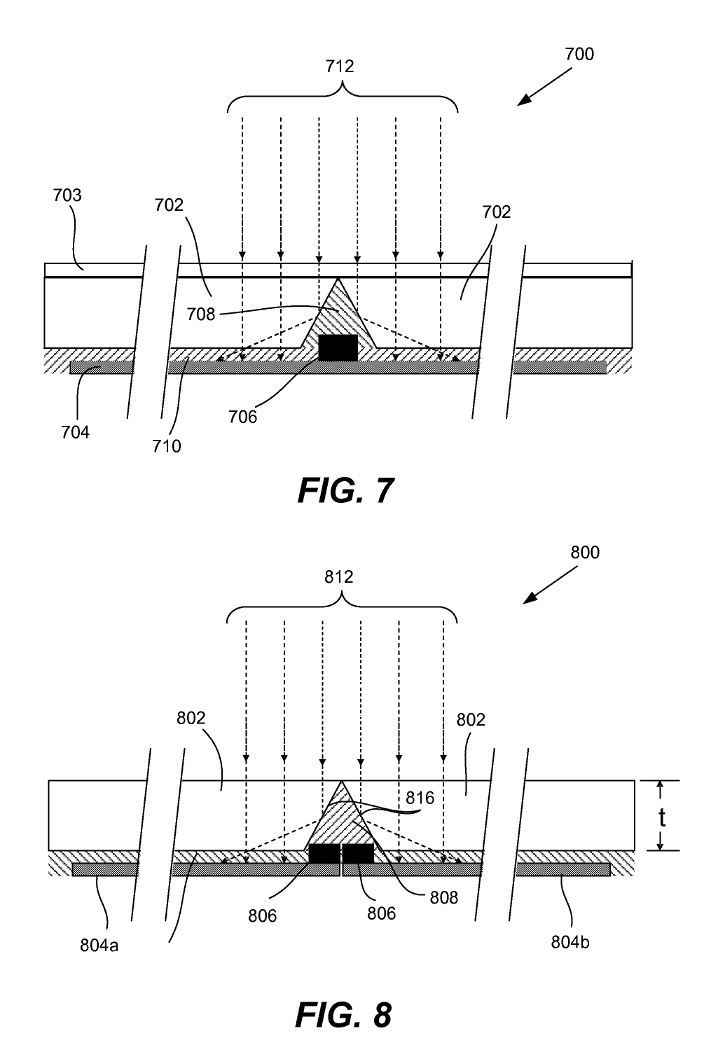

Referring now to FIG. 7, a solar receiver 700 with a top protective layer 703 will be described. Solar receiver 700, which has many of the same features as the solar receiver 500 of FIG. 5, includes a bus bar 706 mounted on a photovoltaic cell 704, first and second encapsulants 708 and 710, one or more protective covers 702 and a flux line 712 that overlaps the bus bar 706. Arranged over the top surface of the protective cover(s) 702 is the top protective layer 703.

The top protective layer 703 helps prevent contaminants and moisture from penetrating through the underlying protective cover(s) 702 and damaging the bus bar 706 and the cell 704. Preferably, the top protective layer 703 helps cover and seal any gap between the protective covers 702. In the illustrated embodiment, for example, the top protective layer has a substantially uniform composition and extends over multiple, distinct protective covers 702. In some implementations, an encapsulant may be used to fill gaps between the protective covers 702 and/or between the protective covers 702 and the top protective layer 703. This encapsulant may be the same as the first encapsulant 708 or the second encapsulant 710, or be made of a different substance. A thickness of approximately 1 mm to 5 mm works well for the top protective layer 703, although other thicknesses are also possible.

Referring next to FIG. 8, a solar receiver 800 that includes two adjacent photovoltaic cells 804a and 804b according to another embodiment of the present invention will be described. The edge portions of the cells each support a bus bar 806 such that the bus bars 806 are also adjacent to one another. The adjacent bus bars 806 are encapsulated in a first encapsulant 808 and are positioned directly under the flux line 812. In the illustrated embodiment, for example, each bus bar 806 is not centrally located with respect to its associated cell, but is centrally located with respect to the flux line 812. Similar to some of the other solar receiver embodiments described herein, edges of the protective covers 802 are positioned adjacent to one another at a location over the bus bars 806. Thus, side beveled surfaces 816 are arranged to reflect light that would otherwise strike one of the bus bars 806 so that the reflected light can reach one of the cells 804a or 804b and be converted into electricity.

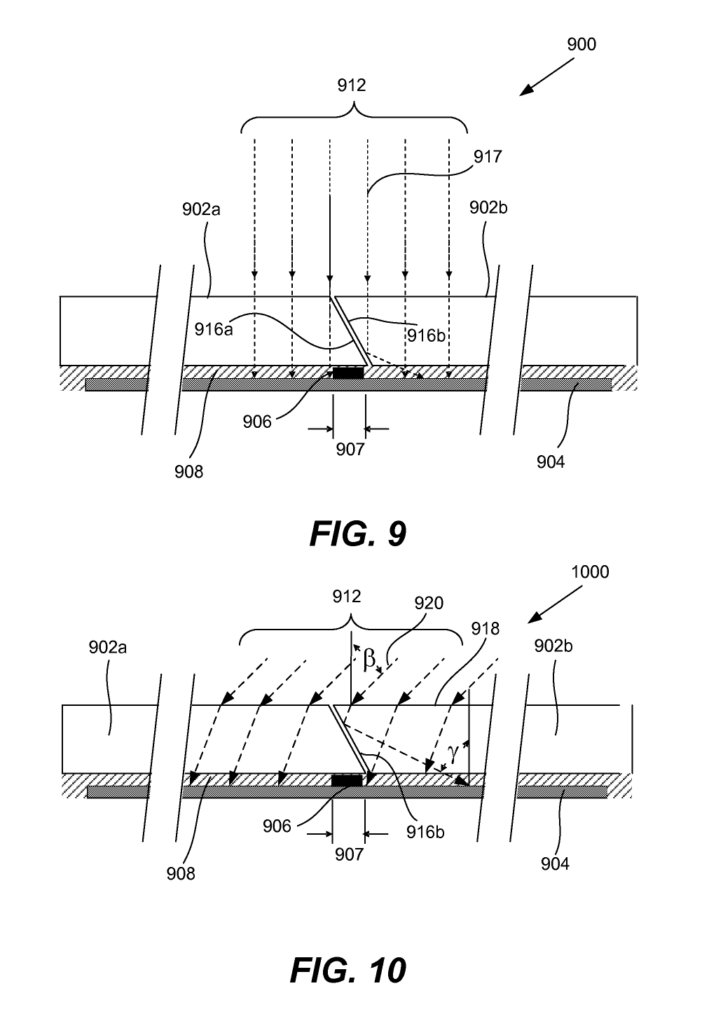

In another embodiment of the present invention, with reference to FIG. 9, a solar receiver 900 with mated, beveled surfaces 916a and 916b will be described. In the illustrated embodiment, a bus bar 906 is mounted on a photovoltaic cell 904, which is covered with a suitable, optically transparent encapsulant 908 (e.g., EVA, silicone, etc.) A flux line 912 overlaps a portion of the cell 904 and the bus bar 906. The protective covers 902a and 902b are positioned on the cell 904 and are arranged to mate over the bus bar 906. The mated, beveled edge surfaces 916a and 916b of the adjacent protective covers 902a and 902b are asymmetric and angled so as to be substantially parallel to one another. The beveled surface 916a of the first protective cover 902a need not be highly reflective. As indicated by the incident sunlight 917, the beveled surface 916b of the second protective cover 902b is arranged to reflect incident sunlight that would otherwise fall on and/or near the bus bar 906. Accordingly, in some embodiments, the beveled surface 916b of the second protective cover 902b helps to form a shadowed region 907 over the bus bar 906, while the beveled surface 916a of the protective cover 902a does not do so.

Like various other solar receiver embodiments described herein, the above arrangement helps to improve cell efficiency. Beveled surface 916b redirects light that might otherwise fall on the bus bar 906 and be wasted. The flux line 912 is arranged to overlap the bus bar 906, which helps reduce the distance that the photo generated electrons need to travel to reach the bus bar 906. The solar receiver 900 may offer additional advantages. In the illustrated embodiment, for example, there is no need for the beveled surfaces of both the first and second protective covers 902a and 902b to be highly reflective. In some preferred embodiments, the beveled surface 916b of the second protective cover 902b is metalized and/or coated with a highly reflective material (e.g., silver, etc.) while the beveled surface 916a of the first protective cover 902a is not. Accordingly, in such embodiments only one of the two mated, beveled surfaces 916a and 916b forms a shadowed region 907 over the bus bar 906. Another advantage is that the mated, beveled surfaces 916 may reduce or eliminate the need to apply encapsulant directly over the bus bar 906 or to form a groove over the bus bar 906. Additionally, the beveled surfaces 916 face and physically support one another, which can reduce the likelihood of mechanical damage at the corners of the protective covers 902a and 902b.

Referring now to FIG. 10, a solar receiver 1000 that is similar to the solar receiver 900 of FIG. 9 will be described, except that the solar receiver 1000 is arranged to receive sunlight that is coming from a particular side. That is, as depicted by the incident sunlight 920, the angular distribution of incoming solar radiation is coming from a direction that is not normal to the face of the photovoltaic cell 904. Accordingly, the solar receiver 1000 may be part of a solar energy collector that tracks the movements of the sun to help ensure that the incident sunlight 920 has the same sense or direction throughout the day. Any solar energy collector that forms a flux line in a suitable manner may be used with the solar receiver 1000, including various solar energy collector designs described in U.S. patent application Ser. No. 12/100,726, which was filed by the assignee of the present application. It should be appreciated that in cases where the incident sunlight always strikes the receiver at an oblique angle, the beveled surface of the protective cover need not be positioned directly above the bus bar to shade the bus bar. Also the angle and length of the bevel can be adjusted so that the bus bar is always shaded during operation. Such a bevel configuration need not shade the bus bar for normally incident light. An exemplary relationship between the angle of incidence β of the light on the protective cover 902b and the angle of incidence γ of the light on the photovoltaic cell 904 is presented in FIG. 12 and is based on one of the solar collector designs described in U.S. patent application Ser. No. 12/100,726.

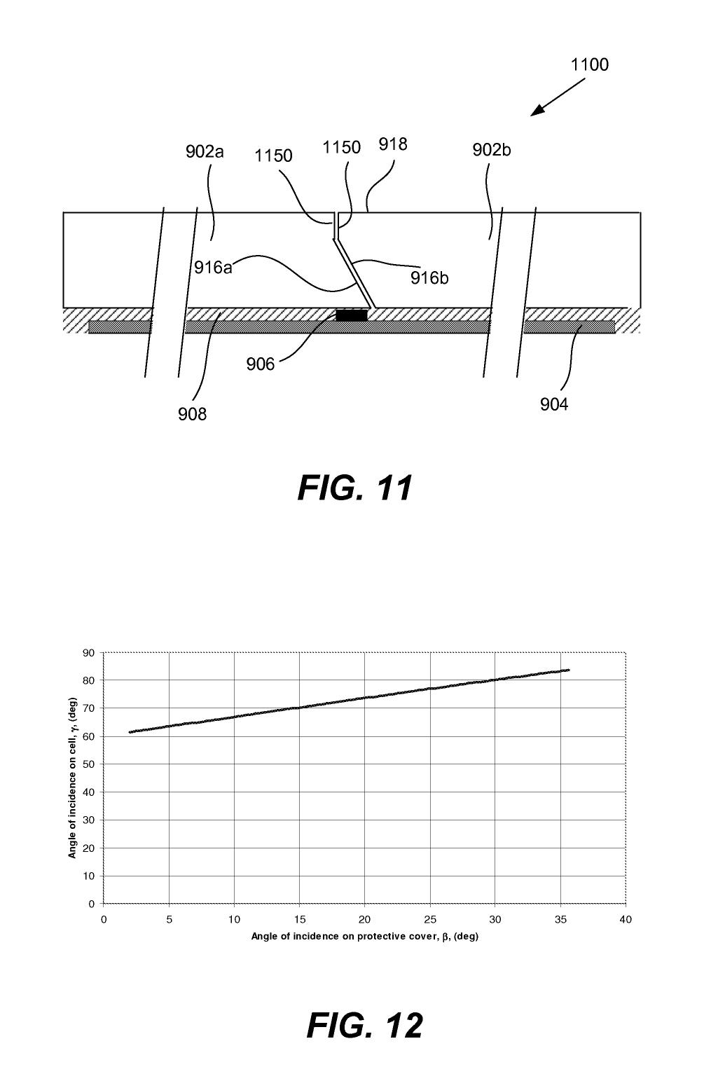

For particular applications, it may be desirable to modify the geometry of the protective covers 902a and 902b of FIGS. 9 and 10. One such modification is shown in FIG. 11. Generally, the solar receiver 1100 has structural characteristics that are similar to the solar receivers depicted in FIGS. 9 and 10. However, in the illustrated embodiment, the sides of the protective covers 902a and 902b do not have uniform slopes. That is, each of the beveled surfaces 916a and 916b, instead of forming a corner with an adjacent top surface 918, instead adjoins a side surface 1150 that extends substantially perpendicular to the face of the underlying cell 904. Each side surface 1150 then forms a corner with the top surface 918 of its respective protective cover. The side surfaces 1150 of the protective covers 902a and 902b face one another and preferably are pressed tightly together. As discussed earlier in connection with FIG. 6, the side surfaces 1150 form an extended region of contact between the protective covers 902a and 902b that may help promote a tighter seal between them. Generally, the reflective properties of the solar receiver 1100 need not be substantially different from those of the solar receivers illustrated in FIG. 9 or 10.

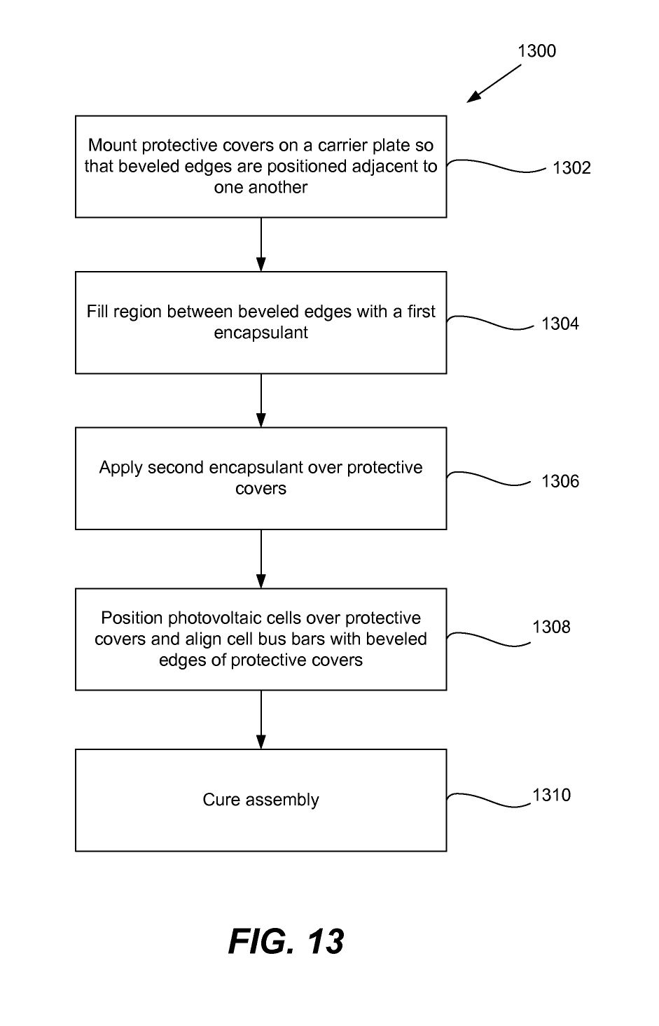

Referring now to FIG. 13, a method for forming a solar receiver will be described. Protective covers having a bevel on at least one side edge are mounted to a carrier plate such that the beveled edges are positioned adjacent to each other (step 1302). Each protective cover also has a top and opposing bottom surface, with the bottom surface being mounted on the carrier plate. The region between the beveled edges may form a v-groove. The region between the beveled edges is then filled at least partially with a first encapsulant (step 1304). The first encapsulant is preferably an optically non-transparent, initially liquid substance that helps prevent contaminants from reaching and damaging the bus bar. Butyl rubber works well as the first encapsulant, although other suitable substances may be used. In various implementations, the first encapsulant may remain in an uncured state or may be cured if an optional second encapsulant is applied over the surface of the protective covers (step 1306). The second encapsulant may take various forms. For example, it may also be a liquid that is deposited over the face of the cell. In another embodiment, the second encapsulant is a solid sheet of protective material that is laminated or otherwise applied over the cell. The second encapsulant may optionally cover or not cover the first encapsulant. EVA or silicone work well as materials for the second encapsulant, although other optically transparent materials may be used as well.

One or more photovoltaic cells are then aligned over and positioned on the top surfaces of the protective covers. The photovoltaic cells each have one or more bus bars and optionally multiple conductive traces. As is well known by persons of ordinary skill in the art, the multiple conductive traces may be formed by applying lines of a conductive material (e.g., silver, etc.) to the face of the photovoltaic cell. The one or more bus bars may be formed by depositing a metal (e.g., copper, etc.) directly over a suitable portion of the conductive traces. Thus, the bus bar is electrically and physically connected to the underlying conductive trace. A bus bar is typically appreciably wider and has a much larger cross section than any single conductive trace. By way of example, the width of a conductive trace may be between approximately 100 and 200 microns, while the width of a bus bar may be between approximately 1 and 3 mm. Thus, a bar bus generally has a much lower series resistance than any single conductive trace.

The photovoltaic cells are positioned so that the bus bars are aligned to the beveled edges of the protective covers (step 1308). In various implementations, the assembly is then cured so that all encapsulant layers are bonded to their surrounding surfaces (step 1310). Some examples of the resulting assembly are illustrated in FIGS. 5-6. The assembly may be incorporated in a solar receiver. It should be appreciated that the above steps and structures may be modified as appropriate to form any of the solar receiver embodiments described herein. It is further noted that other steps may be added to complete the solar receiver, such as removing the carrier, providing a base plate for the photovoltaic cells, and adding a heat sink to the assembly, etc. The order of the assembly may also be varied. For example, the assembly may proceed starting with the photovoltaic cells, applying first encapsulant, optional second encapsulant, and then the protective covers.

Although only a few embodiments of the invention have been described in detail, it should be appreciated that the invention may be implemented in many other forms without departing from the spirit or scope of the invention. In FIGS. 5-11, for example, the solar receiver designs are generally depicted as involving two protective covers and one or two bus bars. However, the present invention contemplates a wide variety of bus bar and protective cover arrangements. For example, the protective cover 502b of FIG. 5, in addition to helping to cover and reflect light away from the bus bar 506 at one end, may be similarly arranged at its opposing end to cover and reflect light away from another bus bar, etc. In some embodiments, a distinct reflector structure may be added over a bus bar and/or a protective cover to help redirect sunlight towards the photovoltaic cell(s). That is, reflection need not necessarily be performed or only performed by the protective cover(s). It should also be appreciated that almost any feature of any embodiment described herein may be used to replace or modify a corresponding feature of another embodiment. For example, although the first encapsulant 508 of FIG. 5 is not specifically referred to in the description and drawing of the solar receiver 800 of FIG. 8, it should be appreciated that the first encapsulant 508 of FIG. 5 may be applied over the bus bars 806 of FIG. 8 in a similar manner. In another example, while FIGS. 3, 4A-4D and 5-11 illustrate various types of protective covers that are positioned over one or more bus bars, such protective covers may also be arranged over and arranged to deflect light away from a wide variety of suitable circuitry, traces, conductive bars, etc. Additionally, any of the solar receivers described herein in connection with FIGS. 3, 4A-4D and 5-11 may be used individually or in any suitable combination in the solar energy collector 200 of FIG. 2. It should also be appreciated that FIG. 5 may be used to help illustrate various steps in the method of FIG. 13 in accordance with a particular embodiment of the present invention. For example, step 1302 of FIG. 13 relates to an arrangement of protective covers on a carrier so that their beveled edges are positioned adjacent to one another. One example of such an arrangement is the protective covers 502a and 502b illustrated in FIG. 5, where beveled edges of the protective covers (i.e., the beveled surfaces 516) are also adjacent to one another. Also described in connection with FIG. 13 are a v-shaped groove filled with a first encapsulant, a second encapsulant, a bus bar and a cell, which in some embodiments can correspond to the v-shaped groove 520 filled with the first encapsulant 508, the second encapsulant 510, the bus bar 506 and the cell 504 of FIG. 5 respectively. Therefore, the present embodiments should be considered as illustrative and not restrictive and the invention is not limited to the details given herein, but may be modified within the scope and equivalents of the appended claims.

What is claimed is:

1. A solar receiver comprising:
a first photovoltaic cell;
a first conductive bar mounted on the first photovoltaic cell;
one or more protective covers that are positioned over the first conductive bar and the first photovoltaic cell, each protective cover including a top surface, an opposing bottom surface and a side beveled surface, the top and bottom surfaces being substantially parallel to a face of the photovoltaic cell, wherein the beveled surface of at least one of the protective covers is positioned over the first conductive bar and arranged to reflect incoming sunlight towards a portion of the first photovoltaic cell that is not covered by the first conductive bar.

2. A solar receiver as recited in claim 1 wherein the one or more protective covers includes a first protective cover and a second protective cover whose top surfaces are substantially coplanar and whose edges are positioned adjacent to one another over the first conductive bar.

3. A solar receiver as recited in claim 2 wherein the beveled surfaces of the first and second protective covers are positioned directly over the first conductive bar to form a v-shaped groove, the first conductive bar being positioned at least partially within the groove.

4. A solar receiver as recited in claim 1 wherein the one or more protective covers each include a side that has a non-uniform slope, the side including the beveled surface and helping to connect the top and bottom surfaces of the protective cover.

5. A solar receiver as recited in claim 1 wherein:
the one or more protective covers are made substantially uniform of glass; and
during normal operation of the solar receiver, there is no other reflective structure in the solar receiver between the protective covers and the first conductive bar that is arranged to reflect light away from the first conductive bar and direct such light towards a portion of the first photovoltaic cell that is not covered by the first conductive bar.

6. A solar receiver as recited in claim 1 wherein the beveled surfaces of the one or more protective covers is coated with a reflective material, while the top and bottom surfaces of the one or more protective covers are not coated with the reflective material.

7. A solar receiver as recited in claim 1 wherein:
the first photovoltaic cell includes an edge region that supports the first conductive bar;
the solar receiver further includes a second photovoltaic cell having an edge region that supports a second conductive bar; and
the edge regions of the first and second photovoltaic cells are positioned adjacent to one another such that the first and second conductive bars are positioned adjacent to one another under the one or more protective covers.

8. A solar receiver as recited in claim 2, further comprising an outer protective layer that is laid over both the first and second protective covers to help seal any openings between and in the first and second protective covers.

9. A solar receiver as recited in claim 2 wherein:
the beveled surfaces of the first and second protective covers slant and mate over the first conductive bar and are substantially parallel to one another; and
the beveled surface of the second protective cover is arranged to direct the incoming sunlight towards a portion of the photovoltaic cell that is not covered by the first conductive bar.

10. A solar energy collector suitable for use in a solar energy collection system that tracks movements of the sun along at least one axis, the solar collector comprising:
a solar receiver including:
a first photovoltaic cell; and
a first bus bar positioned on the first photovoltaic cell, the first bus bar arranged to carry electrical current generated by the first photovoltaic cell; and
a reflective surface coupled with the first photovoltaic cell, the reflective surface arranged to reflect and concentrate incident sunlight to form a flux line that overlaps the first bus bar without entirely covering a cell face of the first photovoltaic cell.

11. A solar energy collector as recited in claim 10 wherein the flux line is a continuous, strip-like region of concentrated sunlight that illuminates a central portion of the first photovoltaic cell such that the flux line does not come in contact with two opposing edges of the first photovoltaic cell.

12. A solar energy collector as recited in claim 10 wherein:
the first bus bar is situated on an edge region of the first photovoltaic cell;
the solar receiver further includes a second photovoltaic cell and a second bus bar, the second bus bar being positioned on an edge region of the second photovoltaic cell;
the edge regions of the first and second photovoltaic cells are positioned adjacent to one another such that the first and second bus bars are positioned adjacent to one another; and
the reflective surface is arranged to form the flux line such that the flux line covers the edge regions and the first and second bus bars of the first and second photovoltaic cells.

13. A solar energy collector as recited in claim 10 wherein:
the first bus bar has a width that is greater than approximately 1 mm; and
the solar receiver further includes a plurality of conductive traces on the photovoltaic cell that are physically and electrically connected to the first bus bar, wherein the conductive traces each have a width of less than approximately 200 microns.

14. A solar energy collector as recited in claim 10, further comprising first and second protective covers that are positioned over the first bus bar and the first photovoltaic cell, the first and second protective covers each including a top surface, an opposing bottom surface and a side beveled surface, the top surfaces of the first and second protective covers being substantially coplanar with one another and being substantially parallel with a face of the photovoltaic cell.

15. A solar energy collector as recited in claim 14, wherein:
the reflective surface is arranged to track the movements of the sun such that the incident light is not perpendicular to the cell face;
the beveled surfaces of the first and second protective covers are arranged substantially parallel to and opposite one another; and
the beveled surface of the second protective cover is arranged to reflect the incident light towards a portion of the photovoltaic cell.

16. A method of forming a solar receiver, the method comprising:
mounting first and second protective covers on a carrier plate, the first and second protective covers having a beveled edge, a top surface and an opposing bottom surface, wherein the top surfaces of the first and second protective covers are mounted on the carrier such that the beveled edges are adjacent to each other; and
positioning a photovoltaic cell over the bottom surfaces of the first and second protective covers, the photovoltaic cell having at least one bus bar, wherein the photovoltaic cell is positioned such that the at least one bus bar is situated beneath the beveled edges of the protective covers.

17. A method as recited in claim 18 wherein the first and second protective covers are made of glass.
